(19) United States
(12) Patent Application Publication
(10) Pub. No.: US 2014/0110857 A1
(43) Pub. Date: Apr. 24, 2014

(54) REDUCTION CHEMISTRY FOR ETCHING

(71) Applicant: Robin Abraham KOSHY, Fishkill, NY (US)

(72) Inventor: Robin Abraham KOSHY, Fishkill, NY (US)

(73) Assignee: GLOBALFOUNDRIES Inc., Grand Cayman (KY)

(21) Appl. No.: 13/659,069

(22) Filed: Oct. 24, 2012

(51) Int. Cl. H01L 21/48; H01L 29/41

(52) U.S. Cl. CPC H01L 21/486; H01L 29/41
USPC 257/774; 438/667

(57) ABSTRACT

An etching is performed with reduction chemistry to prevent erosion of a hard mask. Embodiments include forming a hard mask over one or more layers above a substrate, patterning the hard mask to form openings in the hard mask, and etching the one or more layers with an etchant including hydrogen (H₂) to remove portions of the one or more layers to form one or more vertical interconnect accesses (VIAs)

### TECHNICAL FIELD

The present disclosure relates to etches. The present disclosure is particularly applicable to promoting reduction chemistry during etching for 32 nanometer (nm) technology nodes and beyond.

### BACKGROUND

Etches, such as reactive ion etches (RIEs), are commonly used in the production of semiconductor devices. However, etches are associated with several drawbacks, particularly with respect to hard masks and especially titanium (Ti) hard masks such as titanium nitride (TiN) hard masks. Etches can reduce the effectiveness of hard masks by, for example, eroding the hard mask. In forming specific semiconductor structures, such as merged vertical interconnect accesses (VIAs), such erosion effectively prevents the formation of the intended structure (e.g., the merged VIAs) because the erosion reduces the effectiveness of the hard mask during the dielectric etch. The reduction in the effectiveness of the hard mask also presents issues with respect to trench first metal hard mask (TFMHM) methods, where the hard mask used for the final VIA etching process needs to be precisely controlled. Additionally, erosion of the hard mask creates parasitic residue deposits, for example of Ti, that affect the performance of the resulting semiconductor device.

A need therefore exists for methodology enabling the prevention of the erosion of hard masks by etches, and the resulting devices.

### SUMMARY

An aspect of the present disclosure is an efficient method for performing an etch according to a reducing chemistry.

Another aspect of the present disclosure is a VIA formed by an etch according to a reducing chemistry.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: forming a hard mask over one or more layers above a substrate, patterning the hard mask to form openings in the hard mask, and etching the one or more layers with an etchant including hydrogen (H₂) to remove portions of the one or more layers forming one or more VIAs.

Aspects of the present disclosure include etching with a flow rate of the H₂ of 49.5 to 140 standard cubic centimeters per minute (sccm). An additional aspect includes etching with an etchant power of 50 to 500 watts (W). A further aspect includes the etchant including tetrafluoromethane (CF₄) and nitrogen (N₂). Another aspect includes etching with a combined flow rate of the CF₄ and N₂ of 50 to 500 sccm. Yet a further aspect includes the etchant including octafluorocyclobutane (C₄F₈) and N₂. An additional aspect includes etching with a combined flow rate of the C₄F₈ and N₂ of 10 to 100 sccm. Another aspect includes the etchant including difluoromethane (CH₂F₂) and N₂. A further aspect includes etching with a combined flow rate of the CH₂F₂ and N₂ of 20 to 150 sccm. An aspect includes the etchant being substantially free of oxygen (O₂). An additional aspect includes the one or more layers including one or more interlayer dielectrics (ILDs). In another aspect, the hard mask is a metal hard mask, which may include titanium nitride (TiN).

Another aspect of the present disclosure is a device including: a substrate, an ILD above the substrate, and at least one VIA in the ILD formed by an etch of the ILD including H₂.

Aspects include the VIA being formed with a flow rate of the H₂ in the etchant of 49.5 to 140 sccm. Another aspect includes the VIA being formed with a power of the etchant of 50 to 500 W. An additional aspect includes the VIA being formed with the etchant further including CF₄ and N₂. An additional aspect includes the VIA being formed with a combined flow rate of the CF₄ and N₂ of 50 to 500 sccm. Another aspect includes the etchant being substantially free of oxygen (O₂).

Another aspect of the present disclosure includes: forming a metal hard mask of TiN over an ILD above a substrate, patterning the metal hard mask to form one or more openings corresponding to one or more locations for one or more VIAs in the ILD, and etching the ILD with an RIE including H₂ and being substantially free of O₂ to form recesses in the ILD for the VIAs.

An additional aspect includes etching with a flow rate of the H₂ of 49.5 to 140 sccm and a power of the RIE of 50 to 500 W. Another aspect includes the RIE including at least one of CF₄, C₄F₈, and CH₂F₂.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawings and in which like reference numerals refer to similar elements and in which:

FIGS. 1 through 4 schematically illustrate a process flow for forming a VIA with an etchant according to a reduction chemistry, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problems of eroding hard masks and Ti residue attendant upon performing etches. In accordance with embodiments of the present disclosure, the chemistry associated with the etchant is modified from an oxidation chemistry to a reduction chemistry to reduce the erosion of the hard mask.

Methodology in accordance with embodiments of the present disclosure includes forming a hard mask over one or more layers above a substrate, patterning the hard mask to form openings in the hard mask, and etching the one or more layers with an etchant including H₂ to remove portions of the one or more layers forming one or more VIAs. The etchant may further include at least one of CF₄, C₄F₈, CH₂F₂ and N₂.

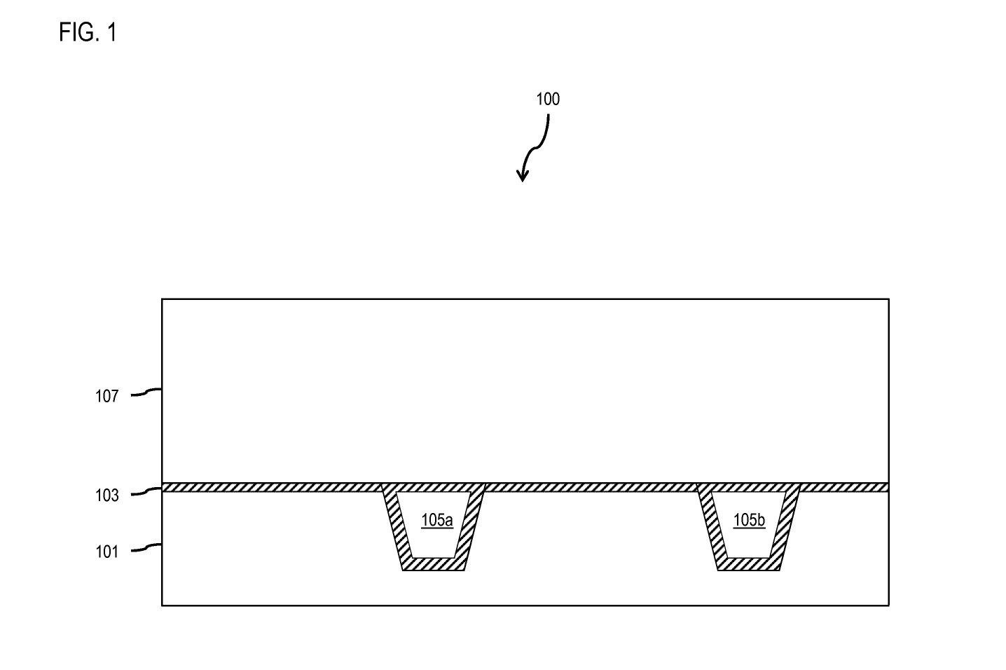

Adverting to FIG. 1, a method of performing an etch for forming a VIA, according to one exemplary embodiment, such as a reactive ion etch (RIE), begins with the structure 100 illustrated in FIG. 1. The structure 100 may include a first dielectric layer 101. Above the first dielectric layer 101 may be a second dielectric layer 103, which may surround metal lines 105a and 105b buried in the first dielectric layer 101. Above the second dielectric layer 103 may be a third dielectric layer 107. However, the structure 100 illustrated in FIG. 1 is merely for illustrative purposes only. Thus, the method of performing an etch is not limited to forming VIAs in only the structure illustrated in FIG. 1.

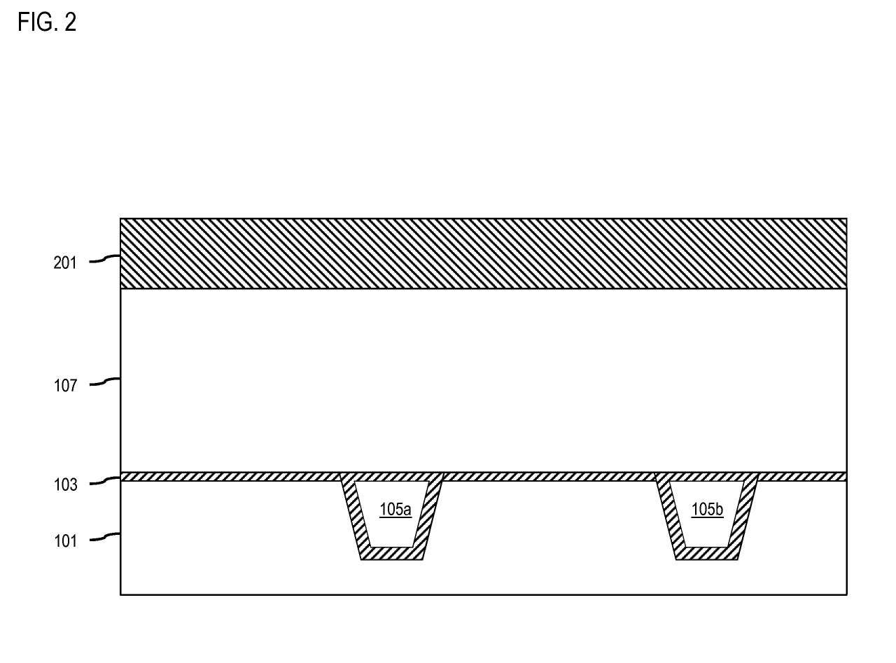

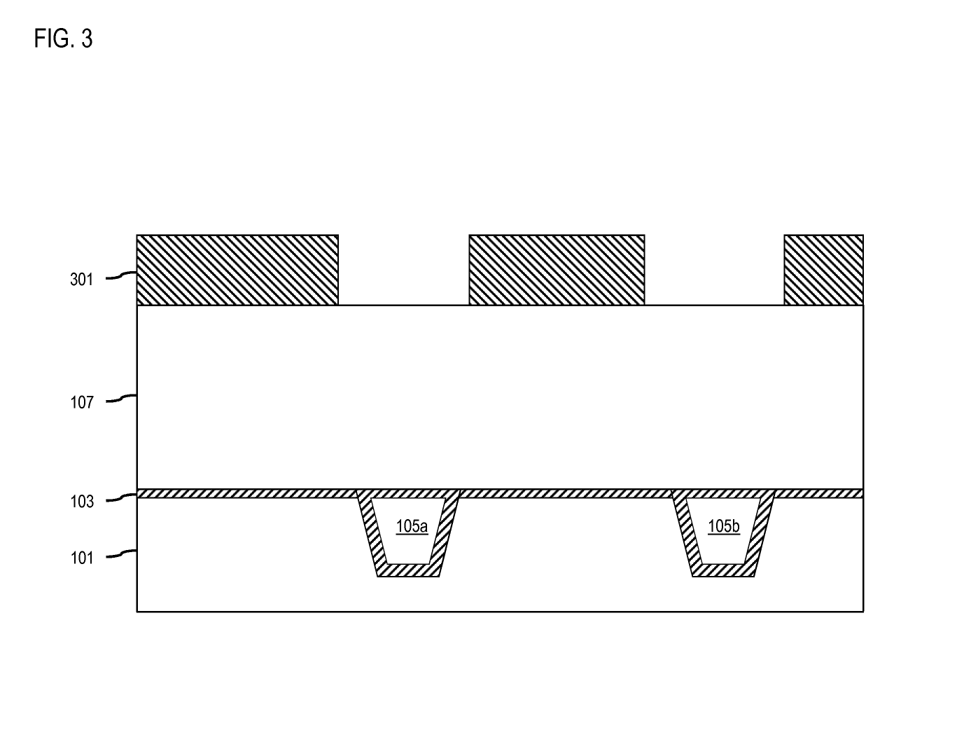

Adverting to FIG. 2, a hard mask 201 may be formed over the third dielectric layer 107. The hard mask 201 may be formed of a metal hard mask, for example a titanium hard mask, e.g., of TiN. Subsequently, the hard mask 201 may be patterned to form a patterned hard mask 301, as illustrated in FIG. 3. The hard mask 201 may be patterned to form openings for forming one or more VIAs. Alternatively, the hard mask 201 may be patterned to form other structures that require removing portions of dielectric layers through an associated hard mask.

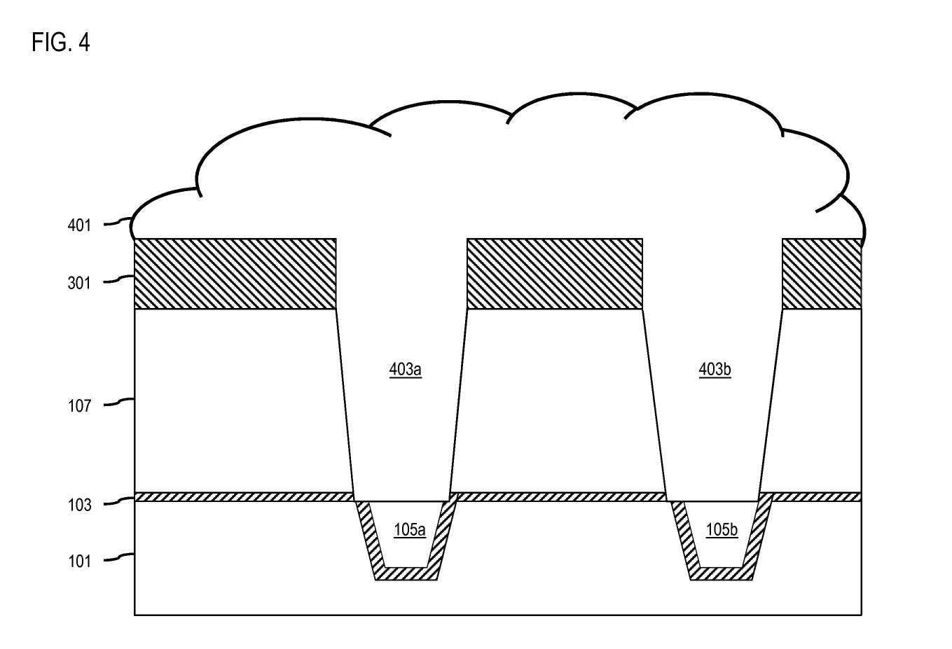

Next, as illustrated in FIG. 4, an etchant 401 may be applied to the patterned hard mask 301 and the exposed areas of the third dielectric layer 107 to etch the third dielectric layer 107. Etching the third dielectric layer 107 may form VIAs 403a and 403b. The etchant 401 may further remove portions of the second dielectric layer 103, thereby exposing the metal lines 105a and 105b. The etchant 401 may include H₂ at a flow rate of 49.5 to 140 sccm and at a power of 50 to 500 W. In addition to the H₂, the etchant 401 may include at least one of CF₄, C₄F₈, CH₂F₂ and nitrogen (N₂). When N₂ and CF₄ are present in the etchant 401, the combined flow rate of the N₂ and CF₄ is 50 to 500 sccm. When N₂ and C₄F₈ are present in the etchant 401, the combined flow rate of the N₂ and C₄F₈ is 10 to 100 sccm. When N₂ and CH₂F₂ are present in the etchant 401, the combined flow rate of the N₂ and CH₂F₂ is 50 to 500 sccm. Further, the step illustrated by FIG. 4 may be the second etch step in a double lithography-double etch process (e.g., litho-etch-litho-etch or LELE) such as in a TFMHM scheme, or a multiple lithography and multiple etch process. However, the step illustrated in FIG. 4, i.e., the etchant 401, may be implemented in any scheme for which a hard mask such as a metal hard mask of TiN is exposed as part of the etch.

By including the H₂ in the etchant 401, the chemistry of the etchant 401 is a reducing chemistry to prevent the erosion of the patterned hard mask 301, which results in improved VIA formation. Further, since a root cause of the TiN etch and erosion is by way of an oxidation pathway, the etchant 401 may be substantially free of O₂ to further promote the reducing chemistry of the etchant 401. The etchant 401 may be substantially free of O₂ such that there is no O₂ in the etchant 401. The etchant 401 may alternatively have a low level of O₂ (e.g., less than 20 sccm) such that the level of the O₂ in the etchant 401 does not affect the reducing chemistry of the etchant 401 and erode the patterned hard mask 301.

Based on the foregoing, the reducing chemistry allows for the formation of advanced semiconductor device features, such as the formation of merged VIAs, which were previously difficult or impossible to produce based on the degradation of the hard mask during the reactive ion etch of dielectric layers below the patterned hard mark to form the VIAs.

The embodiments of the present disclosure achieve several technical effects, including reducing chemistry of etchants (such as RIEs) to allow for the formation of advanced semiconductor features, such as merged VIAs. Embodiments of the present disclosure enjoy utility in various industrial applications as, for example, microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of highly integrated semiconductor devices, particularly for 28 nm technology nodes and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
forming a hard mask over one or more layers above a substrate;
patterning the hard mask to form openings in the hard mask; and
etching the one or more layers with an etchant comprising hydrogen (H₂) to remove portions of the one or more layers forming one or more vertical interconnect accesses (VIAs).

2. A method according to claim 1, comprising etching with a flow rate of the H₂ of 49.5 to 140 standard cubic centimeters per minute (sccm).

3. A method according to claim 1, comprising etching with an etchant power of is 50 to 500 watts (W).

4. A method according to claim 1, the etchant further comprising tetrafluoromethane (CF₄) and nitrogen (N₂).

5. A method according to claim 4, comprising etching with a combined flow rate of the CF₄ and N₂ of 50 to 500 sccm.

6. A method according to claim 1, the etchant further comprising octafluorocyclobutane (C₄F₈) and nitrogen (N₂).

7. A method according to claim 6, comprising etching with a combined flow rate of the C₄F₈ and N₂ of 10 to 100 sccm.

8. A method according to claim 1, the etchant further comprising difluoromethane (CH₂F₂) and nitrogen (N₂).

9. A method according to claim 8, comprising etching with a combined flow rate of the CH₂F₂ and N₂ of 20 to 150 sccm.

10. A method of according to claim 1, wherein the one or more layers comprise one or more interlayer dielectrics (ILDs).

11. A method according to claim 1, wherein the hard mask is a metal hard mask and the etchant is substantially free of oxygen (O₂).

12. A method according to claim 11, wherein the metal hard mask is titanium nitride (TiN).

13. A device comprising:
a substrate;
an interlayer dielectric (ILD) above the substrate; and
at least one vertical interconnect access (VIA) in the ILD formed by an etchant of the ILD comprising hydrogen (H₂).

14. A device according to claim 13, wherein the VIA is formed with a flow rate of the H₂ in the etchant of 49.5 to 140 standard cubic centimeters per minute (sccm) and the etchant is substantially free of oxygen (O₂).

15. A device according to claim 13, wherein the VIA is formed with a power of the etchant of 50 to 500 watts (W).

16. A device according to claim 13, wherein the VIA is formed with the etchant further comprising tetrafluoromethane (CF₄) and nitrogen (N₂).

17. A device according to claim 16, wherein the VIA is formed with a combined flow rate of the CF₄ and N₂ of 50 to 500 sccm.

18. A method comprising:
forming a metal hard mask of titanium nitride (TiN) over an interlayer dielectric (ILD) above a substrate;
patterning the metal hard mask to form one or more openings corresponding to one or more locations for one or more vertical interconnect accesses (VIAs) in the ILD; and
etching the ILD with a reactive ion etch (RIE) comprising hydrogen (H₂), and being substantially free of oxygen (O₂), to form recesses in the ILD for the VIAs.

19. A method according to claim 18, comprising etching with a flow rate of the H₂ of 49.5 to 140 standard cubic centimeters per minute (sccm) and a power of the RIE of 50 to 500 watts (W).

20. A method according to claim 18, the RIE further comprising at least one of tetrafluoromethane (CF₄), octafluorocyclobutane (C₄F₈), and difluoromethane (CH₂F₂).
